(19) United States
(12) Patent Application Publication
(10) Pub. No.: US 2026/0223598 A1
(43) Pub. Date: Jul. 30, 2026

(54) Piezoelectric Device with Cantilever Configuration and Metamaterial for Enhanced Piezoelectric Response

(71) Applicant: Robert Bosch GmbH, Stuttgart (DE)

(72) Inventors: Mordechai KORNBLUTH, Brighton, MA (US); Christoph SCHELLING, Stuttgart (DE); Karim GADELRAB, Watertown, MA (US)

(21) Appl. No.: 19/005,338

(22) Filed: Dec. 30, 2024

(51) Int. Cl. H10N 30/00; B81B 3/00; H10N 30/30; H10N 30/87

(52) U.S. Cl. CPC H10N 30/708; B81B 3/0086; H10N 30/306; H10N 30/308; H10N 30/872; B81B 2201/0257; B81B 2203/0118; B81B 2203/0127; B81B 2203/0307; B81B 2203/04

(57) ABSTRACT

A piezoelectric device includes at least a base and a cantilever. The cantilever has a first end portion anchored by the base and a second end portion unsupported by the base. The cantilever includes at least a piezoelectric element and an augmentation layer. The piezoelectric element includes a first electrode, a piezoelectric layer, and a second electrode. The augmentation supports the piezoelectric element. The augmentation layer has a Poisson's ratio that is less than 0.2 or greater than 0.4.

### TECHNICAL FIELD

This disclosure relates generally to piezoelectric devices, and more particularly to piezoelectric microelectromechanical systems (MEMS) devices with metamaterials and enhanced piezoelectric responses.

### BACKGROUND

MEMS are ubiquitous in modern technology, especially in electronic devices and sensors. MEMS couple mechanics and electricity on a microscale, thereby enabling new paradigms of sensing and processing. One major MEMS market is sonic interaction transducers such as piezoelectric micromachined ultrasonic transducers (PMUTs), microspeakers, and microphones. However, these MEMS devices can be improved so that they operate with improved performance in various applications.

### SUMMARY

The following is a summary of certain embodiments described in detail below. The described aspects are presented merely to provide the reader with a brief summary of these certain embodiments and the description of these aspects is not intended to limit the scope of this disclosure. Indeed, this disclosure may encompass a variety of aspects that may not be explicitly set forth below.

According to at least one aspect, a piezoelectric device includes at least a base and a cantilever. The cantilever has a first end portion anchored by the base and a second end portion unsupported by the base. The cantilever is deformable. The cantilever includes at least a piezoelectric element and metamaterial layer. The piezoelectric element includes a first electrode, a piezoelectric layer, and a second electrode. The metamaterial supports the piezoelectric element. The metamaterial layer includes metastructures. The metamaterial layer is deformable and augments a piezoelectric effect of the piezoelectric layer in response to acoustic pressure such that an augmented voltage differential between the first electrode and the second electrode augments a coupling to a differential in the acoustic pressure.

According to at least one aspect, a microelectromechanical systems (MEMS) device includes at least a base and a cantilever. The cantilever has a first end portion anchored by the base and a second end portion unsupported by the base. The cantilever includes at least a piezoelectric element and an augmentation layer. The piezoelectric element includes a first electrode, a piezoelectric layer, and a second electrode. The augmentation layer is in contact with the first electrode. The augmentation layer has a Poisson's ratio that is less than 0.2 or greater than 0.4.

These and other features, aspects, and advantages of the present invention are discussed in the following detailed description in accordance with the accompanying drawings throughout which like characters represent similar or like parts. Furthermore, the drawings are not necessarily drawn to scale, as some features could be exaggerated or minimized to show details of particular components.

### BRIEF DESCRIPTION OF THE FIGURES

FIG. 1A is a conceptual diagram of a piezoelectric device that includes an example of an augmentation layer according to at least one example embodiment of this disclosure.

FIG. 1B is a conceptual diagram of a piezoelectric device that includes another example of an augmentation layer according to at least one example embodiment of this disclosure.

FIG. 2 is a cross-sectional view of a first example of a piezoelectric device with a membrane configuration that includes an augmentation layer according to at least one example embodiment of this disclosure.

FIG. 3 is a cross-sectional view of a second example of a piezoelectric device with a membrane configuration that includes an augmentation layer according to at least one example embodiment of this disclosure.

FIG. 4 is a cross-sectional view of a first example of a piezoelectric device with a cantilever configuration that includes an augmentation layer according to at least one example embodiment of this disclosure.

FIG. 5 is a cross-sectional view of a second example of a piezoelectric device with a cantilever configuration that includes an augmentation layer according to at least one example embodiment of this disclosure.

FIG. 6 is a cross-sectional view of a third example of a piezoelectric device with a cantilever configuration that includes an augmentation layer according to at least one example embodiment of this disclosure.

FIG. 7 is a cross-sectional view of a fourth example of a piezoelectric device with a cantilever configuration that includes an augmentation layer according to at least one example embodiment of this disclosure.

FIG. 8 is a cross-sectional view of a fifth example of a piezoelectric device with a cantilever configuration that includes an augmentation layer according to at least one example embodiment of this disclosure.

### DETAILED DESCRIPTION

The embodiments described herein, which have been shown and described by way of example, and many of their advantages will be understood by the foregoing description, and it will be apparent that various changes can be made in the form, construction, and arrangement of the components without departing from the disclosed subject matter or without sacrificing one or more of its advantages. Indeed, the described forms of these embodiments are merely explanatory. These embodiments are susceptible to various modifications and alternative forms, and the following claims are intended to encompass and include such changes and not be limited to the particular forms disclosed, but rather to cover all modifications, equivalents, and alternatives falling with the spirit and scope of this disclosure.

Piezoelectric materials are widely employed in sonic interaction transducers owing to their exceptional electro-mechanical properties. These piezoelectric materials exhibit a high-frequency response, allowing for the efficient generation and detection of ultrasonic and/or sound waves crucial in applications such as medical imaging, cleaning processes, distance measurement, sound capture and reproduction, etc. Their compact and lightweight nature makes them suitable for diverse applications with space constraints and portability requirements. Renowned for their durability and stability, these piezoelectric materials ensure reliable performance over time.

Additionally, piezoelectric transducers offer a broad frequency range, thereby enabling adaptation to various operational needs in fields such as medical diagnostics, industrial inspections, automotive sensors, communication, etc. The precision and sensitivity of piezoelectric transducers make them ideal for tasks demanding accurate detection of fine details or subtle changes, for example, as seen in medical imaging, surrounding detection like a park pilot, non-destructive testing, etc. Moreover, their low electrical power consumption contributes to energy efficiency in various devices utilizing ultrasonic or audio technology, respectively. Overall, the unique combination of properties in piezoelectric materials positions them as indispensable components in sonic interaction transducer applications.

In general, piezoelectricity is an electro-mechanical phenomenon observed in specific asymmetric crystal structures, such as quartz and certain ceramics including some perovskites. The direct piezoelectric effect is manifested when a piezoelectric material undergoes physical stress, leading to polarization and the generation of a voltage across it. This piezoelectric effect may be used in MEMS sensors for detecting a deformation of a structural element, such as a membrane or a cantilever. Also, the converse piezoelectric effect occurs when the piezoelectric material is subjected to an electrical field, thereby resulting in deformation, such as an expansion or a contraction, of the structural element depending on the direction of the electric field. In addition, the piezoelectric effect may be used in MEMS actuators for inducing a deformation and/or motion of a structural element.

With respect to measuring a performance of a piezoelectric device, the figure of merit (FoM) is a metric that may be used. For example, regarding a thin-film sensor application (e.g. microphones), the sensitivity or the FoM is described by the piezoelectric coefficient (e_{31,f}) and the relative permittivity (ε_{r,33}) as set forth in equation 1. Also, the FoM for a thin-film ultrasound application is set forth in equation 2, which accounts for an ultrasound wave being exited (e.g., actuation being e_{31,f}) and an incoming ultrasound wave being detected (e.g., sensing being e_{31,f}²/ε_{r,33}). In this regard, ultrasound may refer to sound with frequencies greater than 20 kHz. In addition, the FoM for a thin-film actuator is set forth in equation 3. In general, with respect to these FOM equations, a high value for e_{31,f} is advantageous in generating a high polarization at a given stress. Also, with respect to the FoM set forth in equation 1 and equation 2, a low value for ε_{r,33} is advantageous in yielding higher voltages with a given polarization.

$$Figure of Merit for a thin film sensor = \frac{{e}_{31 , f}}{{ε}_{r , 33}} \qquad [ 1 ]$$

$$Figure of Merit for a thin film ultrsound application = \frac{{e}_{31 , f}^{2}}{{ε}_{r}} \qquad [ 2 ]$$

$$Figure of Merit for a thin film actuator = {e}_{31 , f} \qquad [ 3 ]$$

With respect to these FOM equations, the piezoelectric coefficient, e_{31,f}, is mathematically expressed below in equation 4, where e is the piezoelectric tensor (when written in the stress-charge form), d is the piezoelectric modulus tensor (when written in the strain-charge form), s is the stiffness tensor, c is the elastic tensor, and E is the electric field. In particular, the stress-charge form is defined by equation 5 and equation 6. The strain-charge form is defined by equation 7 and equation 8. In equation 5, equation 6, equation 7, and equation 8, S is the strain, T is the stress, E is the electric field, D is the electric displacement field, ¿ is the relative permittivity at constant stress, and co is the permittivity of free space. Also, the material parameters SE, d, and ET correspond to the material compliance, coupling properties, and relative permittivity at constant stress, respectively. These quantities are tensors of rank 4, 3, and 2, respectively. The tensors, however, are highly symmetric in many high-symmetry crystal structures. They can be represented as matrices within an abbreviated subscript notation, which is usually more convenient.

$${e}_{31 , f} = \frac{{d}_{31}}{{s}_{11}^{E} + {s}_{12}^{E}} = {e}_{31} - \frac{{c}_{13}^{E}}{{c}_{23}^{E}} {e}_{33} \vert {e}_{31 , f} \vert > \vert {e}_{31} \vert \qquad [ 4 ]$$

$$Stress - Charge Form :$$

$$T = {c}_{E} S - {e}^{T} E \qquad [ 5 ]$$

$$D = eS + {ε}_{0} {ε}_{rS} E \qquad [ 6 ]$$

$$Strain - Charge Form :$$

$$S = {s}_{E} T ∓ {d}^{T} E \qquad [ 7 ]$$

$$D = dt + {ε}_{0} {ε}_{rS} E \qquad [ 8 ]$$

Referring back to the FoM equations, the subscript “1” refers to a direction along the nominal x axis, the subscript “2” refers to a direction along the nominal y-axis, and the subscript “3” refers to a direction along the nominal z-axis, which is the direction of polarization. Also, the first subscript of the piezoelectric tensors gives the direction of the electrical field associated with the voltage applied or the charge produced. The second subscript of the piezoelectric tensors gives the direction of mechanical stress or strain. The subscript “f” refers to the film being “free” (e.g., “unclamped”) and enabled to move along the vertical direction, z, perpendicular to the thin film.

Also, with respect to the FoM equations, AlN is preferred over lead zirconate titanate (PZT) with respect to its relative permittivity being much lower. Also, with respect to AlN, the FoM may be further improved by doping AlN with Sc to produce, for example, Al_{0.6}Sc_{0.4}N or Al₁₋ₓScₓN (where x represents a suitable number). Other piezoelectric materials including an assortment of wurtzite and perovskite crystal structures and their derivatives may also be used. However, PZT exhibits a superior piezoelectric coefficient (or piezoelectric constant), e_{31,f}, as piezoelectric constants vary with respect to doping ratio and material, which has advantages for actuator applications. Additionally, the FoM for actuators is denoted as e_{31,f} and PZT is one of the most studied and commercially used material for applications in actuators like micro-mirrors.

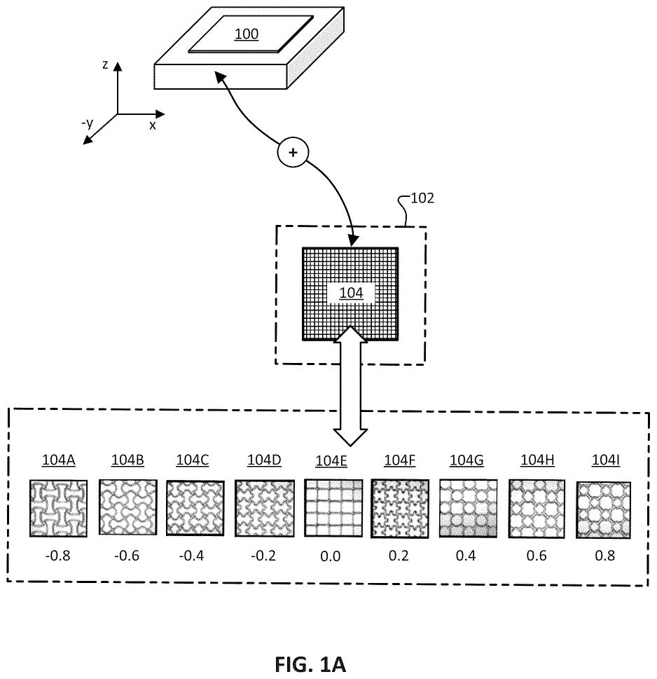

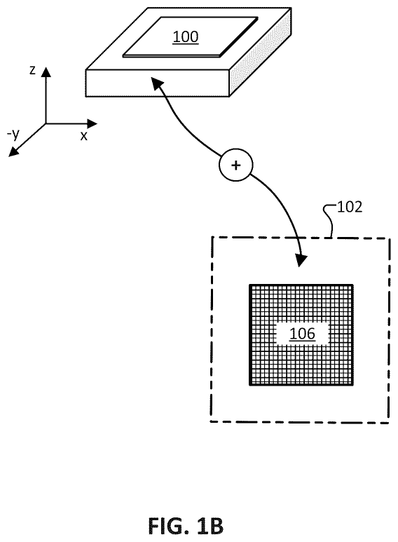

FIG. 1A and FIG. 1B illustrate perspective views of examples of piezoelectric devices 100, which include piezoelectric elements to detect deformations of structural elements. Although FIG. 1A and FIG. 1B illustrate the piezoelectric devices 100 as comprising square configurations, the piezoelectric devices 100 are not limited to these configurations. These piezoelectric devices 100 may comprise any applicable configuration. For example, the piezoelectric devices 100 may comprise round or circular configurations. The piezoelectric devices 100 may comprise rectangular or polygonal configurations. The piezoelectric components may also comprise rectangular, round, ellipsoid, or polygonal configurations.

In FIG. 1A and FIG. 1B, the piezoelectric devices 100 are MEMS devices, where each MEMS device includes a membrane or a cantilever as a structural element. For a MEMS device with a piezoelectric element that includes a thin piezoelectric film clamped on a substrate, the FoM includes the piezoelectric coefficient, e_{31,f}, as a key component, as discussed above. Specifically, for this piezoelectric device 100, the piezoelectric coefficient, e_{31,f}, is mathematically computed via equation 9, where the notation (e.g., variables, subscripts, and superscripts) is the same as discussed above with respect to equation 1, equation 2, equation 3, and equation 4.

$${e}_{31 , f} = {e}_{31} - \frac{{c}_{13}^{E}}{{c}_{33}^{E}} {e}_{33} \vert {e}_{31 , f} \vert > \vert {e}_{31} \vert \qquad [ 9 ]$$

Recognizing that the FoM is affected by the Poisson's ratio, v, via the piezoelectric coefficient, e_{31,f}, the piezoelectric device 100 combines the piezoelectric device 100 with at least an augmentation layer 102, which is structured and/or engineered to have a Poisson's ratio that optimizes a performance of the piezoelectric device 100. Specifically, in this example, the Poisson's ratio, v, is mathematically defined via equation 10. For example, given that the piezoelectric coefficient, e_{31,f}, is typically less than zero and ε₃₃ is typically greater than zero, a Poisson's ratio, v, that has a very high value can increase the FoM. Alternatively, or additionally, a piezoelectric auxetic material may have e₃₁>0 and a negative Poisson's ratio, v<0, which produces a high FoM.

$$v = \frac{{c}_{13}^{E}}{{c}_{33}^{E}} \qquad [ 10 ]$$

Referring to FIG. 1A, the piezoelectric device 100 achieves improved performance (e.g., increased FoM) by adding an augmentation layer 102 that is configured to enhance the piezoelectric response. The augmentation layer 102 comprises a single metamaterial layer 104 or a plurality of metamaterial layers 104. The plurality of metamaterial layers 104 may form a composite metamaterial layer. The metamaterial layer 104 has a Poisson's ratio that is within a specified range, which is determined to enhance a performance of the piezoelectric device 100. The metamaterial layer 104 comprises an engineered material that has at least one property that is not found in the material or materials that the metamaterial layer 104 is comprised of. For example, the metamaterial layer 104 may comprise silicon, silicon dioxide, silicon nitride, silicon carbide, a metal oxide, etc. Also, the metamaterial layer 104 includes one or more types of metastructures. The metastructures are generated at the micro scales or the nano scales, thereby allowing for precise control over their mechanical properties and behavior. In some embodiments, the metastructures are formed and oriented out-of-plane (e.g., the xz-plane) with respect to the piezoelectric device 100. With respect to being out-of-plane (e.g., xz-plane), the metastructures are formed and oriented perpendicular to a contact surface of the metamaterial layer. The contact surface may be defined as the surface that contacts the substrate (or another layer). In other embodiments, the metastructures are formed and oriented in-plane (e.g., the xy-plane). With respect to being in-plane (e.g., xy-plane), the metastructures are formed and oriented parallel to the aforementioned contact surface of the metamaterial layer. Additionally or alternatively to the metamaterial layer 104, the piezoelectric device 100 includes one or more types of metastructures on one or more of the other layers of the piezoelectric device 100. For example, the metastructures may be formed on the first electrode, the piezoelectric layer, the second electrode, the sealing layer, the intermediate layer, the substrate, the base, or any number and combination thereof. The piezoelectric device 100 is configured to include one or more types of metastructures, which are selected based on a number of considerations (e.g., desired Poisson's ratio, desired technical application, desired fabrication, desired costs, etc.).

As non-limiting examples, FIG. 1A illustrates different types of lattice samples 104A-1041 that are constructed from different types of metastructures. FIG. 1A shows each one of the lattice samples 104A and 1041 as being formed and oriented on a plane. The piezoelectric device 100 may include one or more of the lattice types shown in 104A-1041, where a particular lattice would be formed and orientated, as shown in FIG. 1A, on an xy-plane or an xz-plane of a particular layer (e.g., metamaterial layer 104 or another layer), as discussed above. Specifically, each lattice sample includes a metastructure motif with a pattern of metastructures. For example, a metastructure motif may include one or more honeycombs, triangles, stars, arrowheads, sinusoids, folded plates, missing ribs, an auxetic shape/structure, or any suitable number and combination thereof. The one or more metastructures may be characterized as re-entrant geometry, chiral, rotating, interlocking, etc. The metastructures are formed by an additive structure formation method, a subtractive structure formation method, or a combination of additive and subtractive formation methods. Also, as demonstrated by these lattice samples 104A to 1041, the metastructure motifs are structured to provide various Poisson's ratios. For example, the first lattice sample 104A has a first metastructure motif and a Poisson's ratio of −0.8, thereby being an auxetic pattern. The second lattice sample 104B has a second metastructure motif and a Poisson's ratio of −0.6, thereby being an auxetic pattern. The third lattice sample 104C has a third metastructure motif and a Poisson's ratio of −0.4, thereby being an auxetic pattern. The fourth lattice sample 104D has a fourth metastructure motif and a Poisson's ratio of −0.2, thereby being an auxetic pattern. The fifth lattice sample 104E has a fifth metastructure motif and a Poisson's ratio of 0.0. The sixth lattice sample 104F has a sixth metastructure motif and a Poisson's ratio of 0.2. The seventh lattice sample 104G has a seventh metastructure motif and a Poisson's ratio of 0.4. The eighth lattice sample 104H has an eighth metastructure motif and a Poisson's ratio of 0.6. The ninth lattice sample 104I has a ninth metastructure motif and a Poisson's ratio of 0.8.

Referring to FIG. 1B, the piezoelectric device 100 achieves improved performance (e.g., increased FoM) by adding an augmentation layer 102 that is configured to enhance the piezoelectric response. In FIG. 1B, the augmentation layer 102 comprises a particular material layer 106 having a desired Poisson's ratio, which is determined to enhance a performance of the piezoelectric device 100 depending upon the application. For example, the particular material layer 106 comprises a material is atomically auxetic. Auxetic behavior may be correlated with strong elastic anisotropy, which may induce negative Poisson's ratio in certain directions, under specific loading conditions. For instance, the particular material layer 106 may comprise α-cristobalite (SiO₂), as the elasticity of alpha-cristobalite silicon oxide has a negative Poisson's ratio. The particular material layer 106 may comprise HT-AIPO4 (the high temperature form of AlPO4). The particular material layer 106 may be an anepirretic material, i.e. one with a near-zero Poisson's ratio.

In FIG. 1B, as another example, the particular material layer 106 comprises one or more of the crystalline materials selected from TABLE 1. In this regard, a number of crystalline materials have been found to exhibit desired Poisson's ratios (e.g., low or negative Poisson's ratios) in certain directions due to specific features of their crystal structure. This is typically associated with rigid units within the materials microstructure that exhibit coordinated rotational motion during structural deformation. Specifically, TABLE 1 provides a list of some materials, which have been computationally screened and selected for the augmentation layer 102 for having at least one desired property (e.g., a desired Poisson's ratio) for achieving an improved piezoelectric response of the piezoelectric device 100.

TABLE 1

| | Poisson's ratio |
|---|---|
| Material | (Approximation) |
| 4H—SiC | 0.2 |
| 6H—SiC | 0.2 |
| Diamond | 0.07 |
| Nickel | 0.3 |
| Boron Nitride, graphene, or | 0.1 to 0.2 |
| other monolayer materials | |
| Silicon Oxide | 0.15 to 0.2 |
| Copper | 0.34 |
| Nickel Alloys | 0.26 to 0.45 |

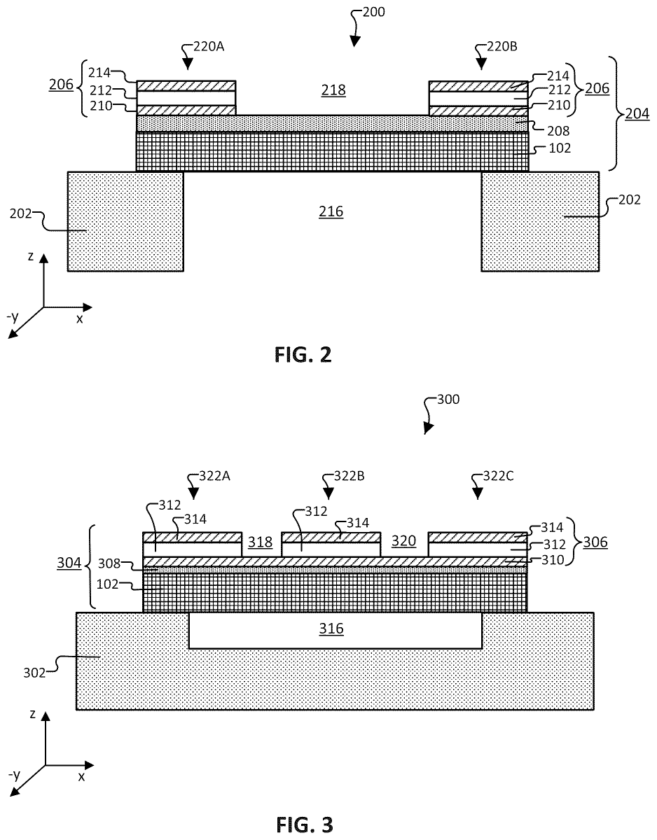

FIG. 2 and FIG. 3 illustrate cross-sectional views of examples of different piezoelectric devices 100 with different membrane configurations that each include at least the augmentation layer 102 for an enhanced piezoelectric response. In general, the membrane configurations include a composite membrane 204/304 that is supported at both ends by a substrate 202/302 while being unsupported at a central portion thereof such that the composite membrane 204/304 is provided with sufficient space to deform, flex, bend, vibrate, and/or move. For conceptual understanding, the deformation of the composite membrane 204/304 may be likened in some respects to the deformation of a drum. In these examples, the composite membrane 204/304 may include at least the piezoelectric element 206/306 (e.g., the first electrode, piezoelectric layer, and the second electrode), an intermediate layer 208/308 (e.g., sealing layer, isolation layer, etc.), and the augmentation layer 102. In this regard, in response to acoustic pressure, the structural element of the composite membrane 204/304 is configured to deform and provide an augmented voltage differential across a pair of electrodes. Also, in some examples, the thin piezoelectric layer 212/312 deforms in response to an external field (e.g. a sound wave) and induces a voltage, or a voltage is induced to create a sound wave thereby creating a microphone.

Referring to FIG. 2, as an example, the piezoelectric device 100 is configured as MEMS device 200 (e.g., microspeaker, microphone, etc.). The MEMS device 200 includes at least a substrate 202 and a composite membrane 204. The substrate 202 is inorganic or semiconducting. The substrate 202 includes silicon (e.g. silicon wafer), silicon carbide, a metal oxide, glass, sapphire, silicon oxide, silicon nitride, or an applicable substrate material for the MEMS device 200. As shown in the cross-sectional view of FIG. 2, the substrate 202 includes a cavity 216. The cavity 216 is located at a central region of the substrate 202. The cavity 216 is defined as a through-hole that extends entirely through the substrate 202 from one end surface to an opposite end surface. The substrate 202 provides a frame-like structure that includes side portions or opposite end portions, which define bounds of the cavity 216 and which provide support for the composite membrane 204.

The composite membrane 204 is disposed on the substrate 202. As shown in FIG. 2, the composite membrane 204 is disposed over and across the cavity 216 while being supported by the opposite end portions of the substrate 202. The composite membrane 204 comprises a piezoelectric element 206, an intermediate layer 208, and the augmentation layer 102. The composite membrane 204 is disposed on one side (e.g., frontside) of the substrate 202. Specifically, the augmentation layer 102 is in contact with at least the side portions or the end portions of the substrate 202. The augmentation layer 102 is sandwiched between the substrate 202 and the Intermediate layer 208. The Intermediate layer 208 is in contact with the augmentation layer 102. The Intermediate layer 208 is sandwiched between the augmentation layer 102 and the piezoelectric element 206. In this example, the intermediate layer 208 is a sealing layer, which is formed across an entire length of the augmentation layer 102 along at least the x-axis. In this regard, the intermediate layer 208 may cover an entire top surface of the augmentation layer 102. The sealing layer 208 is advantageous in preventing leakage across the composite membrane 204.

The piezoelectric element 206 is in contact with the Intermediate layer 208. The piezoelectric element 206 includes a first electrode 210, a piezoelectric layer 212, and a second electrode 214 arranged in a vertical stack. The first electrode 210 is in contact with the Intermediate layer 208. The piezoelectric layer 212 is between the first electrode 210 and the second electrode 214. In particular, the piezoelectric layer 212 has one side in contact with the first electrode 210 and an opposite side in contact with the second electrode 214. In addition, the piezoelectric element 206 includes a gap 218 that exposes a central part of the Intermediate layer 208 and provides the central part of the composite membrane 204 with the space to deform, flex, bend, vibrate, and/or move. Specifically, as shown in FIG. 2, a central portion of the Intermediate layer 208 is exposed via the gap 218. Also, the gap 218 separates the piezoelectric element 206 into a first piezoelectric section 220A and a second piezoelectric section 220B. As shown in FIG. 2, the first piezoelectric section 220A is spaced from the second piezoelectric section 220B along the x-axis via the gap 218. The first piezoelectric section 220A includes the first electrode 210, the piezoelectric layer 212, and the second electrode 214. The second piezoelectric section 220B includes the first electrode 210, the piezoelectric layer 212, and the second electrode 214.

With respect to FIG. 2, the MEMS device 200 may be fabricated in a number of different ways. As one example, the method may include depositing an augmentation layer 102 on a substrate 202. The substrate 202 comprises at least one material, as discussed above. The substrate 202 may have a thickness that is no greater than 0.5 mm. When the augmentation layer 102 comprises one or more metamaterial layers 104, the method includes forming one or more types of metastructures on the augmentation layer 102 using additive and/or subtractive structure formation methods. The method includes forming a Intermediate layer 208 on the augmentation layer 102. Next, the method includes depositing a first electrode 210 on the Intermediate layer 208. The first electrode 210 may be deposited via physical vapor deposition, chemical vapor deposition, electroplating, sputtering, or any other deposition method. The first electrode 210 comprises platinum, aluminum, gold, molybdenum, tungsten, or another conductor of approximately 100 nm in thickness. The method includes depositing a piezoelectric layer 212 (e.g., PZT, AlN, Al₁₋ₓScₓN, or another piezo material) via sputtering, molecular beam epitaxy, or another deposition method. The piezoelectric layer 212 may have a thickness that is within a range of 0.5 μm to 2 μm. The method includes depositing a second electrode 214 on the piezoelectric layer 212. The second electrode 214 is deposited via a method similar to or different from the deposition of the first electrode 210. The second electrode 214 comprises platinum, aluminum, gold, molybdenum, tungsten, or another conductor of approximately 100 nm in thickness. The first electrode 210, the piezoelectric layer 212, and the second electrode 214 are formed as shown in FIG. 2 with a gap 218 therebetween. The method includes removing or etching away a portion of the substrate 202 to create the cavity 216 in the substrate 202 such that a part of the composite membrane 204 is suspended. In addition, the removal of a portion of the substrate 202 exposes a bottom surface of the augmentation layer 102. The bottom surface of the augmentation layer 102 may be directly exposed to an environment of the cavity 216. Furthermore, in addition to the metamaterial layer 104, if desired, the metastructures may be formed on one or more of the other layers that comprise the composite membrane 204 at a suitable time via additive and/or subtractive structure formation methods. In this example, the composite membrane 204 comprises dimensions within a range of 100 μm×100 μm to 5 mm×5 mm.

Referring to FIG. 3, as an example, the piezoelectric device 100 is configured as MEMS device 300 (e.g., a PMUT, etc.). The MEMS device 300 comprises at least a substrate 302 and a composite membrane 304. The substrate 302 is inorganic or semiconducting. The substrate 302 includes silicon (e.g., silicon wafer), silicon carbide, a metal oxide, glass, sapphire, silicon oxide, silicon nitride, or an applicable substrate material for the MEMS device 300. Also, as shown in FIG. 3, the substrate 302 includes a cavity 316 in a central portion thereof. The cavity 316 is located on a front side of the substrate 302. The substrate 302 defines the cavity 316 such that the cavity 316 forms a recessed portion within the substrate 302. That is, as shown in FIG. 3, the cavity 316 is not formed as a through-hole in the substrate 302. In this example, the front side refers to a side of the substrate 302 on which the composite membrane 304 is disposed. The substrate 302 provides a structure that includes side portions or opposite end portions, which define bounds of the cavity 316 and which provide support for the composite membrane 304. As aforementioned, in this example, the cavity 316 does not fully extend through the substrate 302. Instead, the substrate 302 is provided with a recessed portion via the cavity 316. An overall thickness of an end portion of the substrate 302 is greater than an overall thickness of the recessed portion of the substrate 302. Also, the composite membrane 304 overlaps the recessed portion of the substrate 302. The recessed portion of the substrate 302 corresponds to the unsupported part of the composite membrane 304 and provides space for the composite membrane 304 to deform, flex, bend, or move.

The composite membrane 304 is disposed on one side (e.g., a frontside) of the substrate 302. The composite membrane 304 is disposed over and across the front side of the cavity 316 while being supported by side portions or opposite end portions of the substrate 302. The composite membrane 304 may include a piezoelectric element 306, an intermediate layer 308, and the augmentation layer 102. In this example, the intermediate layer 308 is a dielectric layer, an insulating layer, or an interlayer for isolation purposes. Also, as shown in FIG. 3, the augmentation layer 102 is in contact with the side portions or the end portions of the substrate 302. The augmentation layer 102 is between the substrate 302 and the intermediate layer 308. The intermediate layer 308 is in contact with the augmentation layer 102. The intermediate layer 308 is sandwiched between the augmentation layer 102 and the piezoelectric element 206. In this example, the intermediate layer 308 extends across an entire length of the augmentation layer along at least the x-axis. In this regard, the intermediate layer 308 may cover an entire top surface of the augmentation layer 102.

The piezoelectric element 306 is disposed on the intermediate layer 308. The piezoelectric element 306 includes a first electrode 310, a piezoelectric layer 312, and a second electrode 314 arranged in a vertical stack. Specifically, the first electrode 310 is in contact with the intermediate layer 308. Moreover, as shown in FIG. 3, the first electrode 310 extends along the entire length of the composite membrane 304. Specifically, the first electrode 310 extends along the entire length of the intermediate layer 308 along at least the x-axis. In this example, the first electrode 310 is configured to provide the functions of both a conductive electrode and a sealing layer. By being formed across the entirety of the composite membrane 304, the first electrode 310 prevents leakage across the composite membrane 304.

The piezoelectric layer 312 is between the first electrode 310 and the second electrode 314. The piezoelectric layer 312 has one side in contact with the first electrode 310 and an opposite side in contact with the second electrode 314. In addition, the piezoelectric element 306 includes a first piezoelectric section 322A, a second piezoelectric section 322B, and a third piezoelectric section 322C. These piezoelectric sections are defined by a first gap 318 and a second gap 320, which are defined in the piezoelectric layer 312 and the second electrode 314. Also, as shown in FIG. 3, there are portions of the corresponding surfaces of the first electrode 310 that are exposed by the first gap 318 and the second gap 320. In this example, the first gap 318 and the second gap 320 are the same size or substantially the same size to provide uniform spacing between the piezoelectric sections. However, the piezoelectric sections are not limited to this uniform arrangement. Also, the first piezoelectric section 322A includes at least a first section of the first electrode 310, a first section of the piezoelectric layer 312, and a first section of the second electrode 314. The second piezoelectric section 322B includes at least a second section of the first electrode 310, a second section of the piezoelectric layer 312, and a second section of the second electrode 314. The third piezoelectric section 322C includes at least a third section of the first electrode 310, a third section of the piezoelectric layer 312, and a third section of the second electrode 314.

Referring to FIG. 3, the MEMS device 300 may be fabricated in a number of different ways. As one example, the method may include depositing an augmentation layer 102 on a substrate 302. The substrate 302 comprises at least one material, as discussed above. The substrate 302 may have a thickness that is no greater than 0.5 mm. When the augmentation layer 102 comprises one or more metamaterial layers 104, the method includes forming one or more types of metastructures on the augmentation layer 102 using additive and/or subtractive structure formation methods. The method includes depositing an intermediate layer 308 on the augmentation layer 102. Next, the method includes depositing a first electrode 310 on the intermediate layer 308. The first electrode 310 may be deposited via physical vapor deposition, chemical vapor deposition, electroplating, sputtering, or any other deposition method. The first electrode 310 comprises platinum, aluminum, gold, molybdenum, tungsten, or another conductor of approximately 100 nm in thickness. The first electrode 310 is formed across the entire length of the intermediate layer 308. The method includes depositing a piezoelectric layer 312 (e.g., PZT, AlN, Al₁₋ₓScₓN, or another piezo material) via sputtering, molecular beam epitaxy, or another deposition method. The piezoelectric layer 312 may have a thickness that is within a range of 0.5 μm to 2 μm. The method includes depositing a second electrode 314 on the piezoelectric layer 312. The second electrode 314 is deposited via a method similar to or different from the deposition of the first electrode 310. The second electrode 314 comprises platinum, aluminum, gold, molybdenum, tungsten, or another conductor of approximately 100 nm in thickness. The piezoelectric layer 312 and the second electrode 314 are formed with a first gap 318 and a second gap 320 to create the three piezoelectric sections 322A, 322B, and 322C, as shown in FIG. 3. The method includes removing or etching away a portion of the substrate 302 to create the cavity 316 and form a recessed portion in the substrate 302 such that a part of the composite membrane 304 is suspended and unsupported by the substrate 302. In addition, the removal of a portion of the substrate 302 exposes a bottom surface of the augmentation layer 102. The bottom surface of the augmentation layer 102 may be directly exposed to an environment of the cavity 316. Furthermore, in addition to the metamaterial layer 104, if desired, the metastructures may be formed on one or more of the other layers that comprise the composite membrane 304 at a suitable time via additive and/or subtractive structure formation methods. In this example, the composite membrane 304 comprises dimensions within a range of 100 μm×100 μm to 5 mm×5 mm.

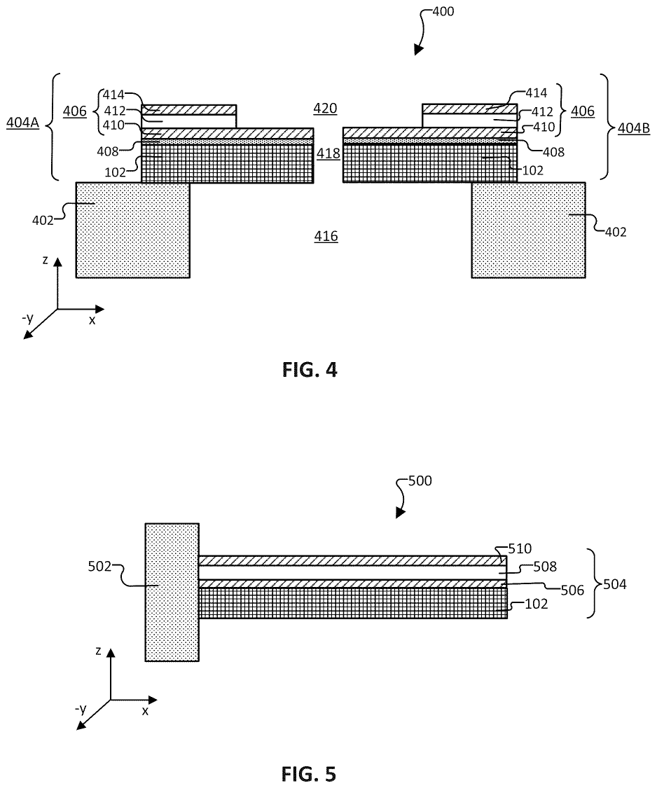

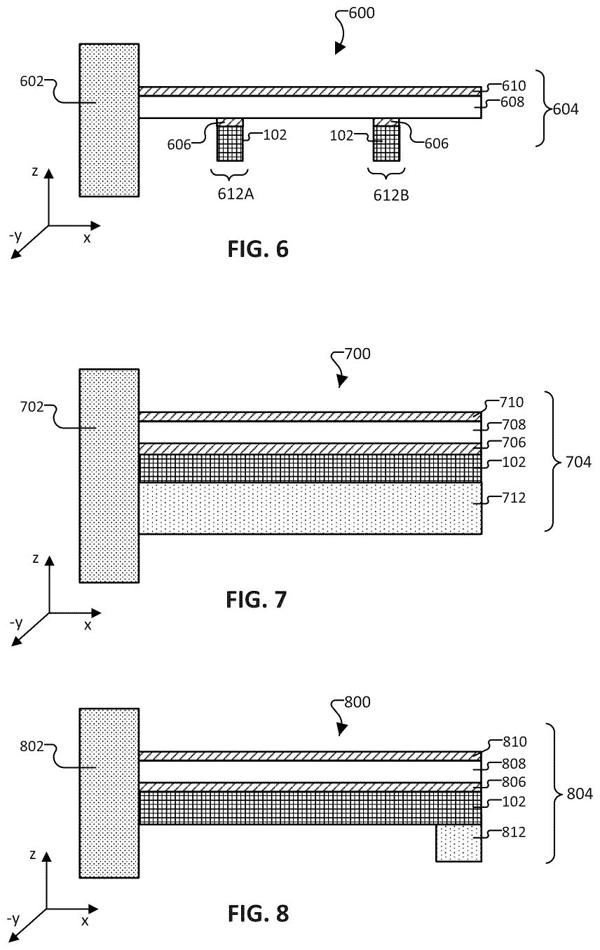

FIG. 4, FIG. 5, FIG. 6, FIG. 7, and FIG. 8 illustrate cross-sectional views of examples of different piezoelectric devices 100 with various cantilever configurations that each include at least the augmentation layer 102 for enhancing the piezoelectric response. Each cantilever configuration includes a cantilever, which is a deformable beam that is anchored at one end portion while being unsupported and free to move at the other end portion. The cantilever itself may differ in a number of different ways. For example, the cantilever may include one or more electrodes that cover all of the piezoelectric layer (e.g., FIG. 5, FIG. 7, and FIG. 8) or part of the piezoelectric layer (e.g., FIG. 4, FIG. 6). The cantilever may include a substrate (e.g., FIG. 4 and FIG. 7). Alternatively, the cantilever may include a substrate, which is entirely removed (e.g., FIG. 5 and FIG. 6) or partially removed (e.g., FIG. 4 and FIG. 8) when fabricating the piezoelectric device. The cantilever may include a weight (e.g., FIG. 8) at one end portion to enhance the deflection. There may also be other variations to these cantilever configurations.

For conceptual understanding, the deformation of the cantilever may be likened in some respects to the deformation of a yardstick that is supported at one end portion thereof. Given a cantilever configuration, the voltage is measured between a first electrode of the cantilever and a second electrode of the cantilever. Also, the cantilever may move or become deformed via an applied voltage. Furthermore, in response to acoustic pressure, the structural element of the cantilever is deformable and provides enhanced piezoelectric response and an increased FoM with the addition of the augmentation layer 102.

Referring to FIG. 4, as an example, the piezoelectric device 100 is configured as MEMS device 400 (e.g., microspeaker, microphone, etc.). The MEMS device 400 comprises a dual cantilever configuration on a substrate 402. The substrate 402 is inorganic or semiconducting. The substrate 402 includes silicon (e.g., silicon wafer), silicon carbide, a metal oxide, glass, sapphire, silicon oxide, silicon nitride, or an applicable substrate material for the MEMS device 400. As shown in FIG. 4, the substrate 402 includes a cavity 416 in a central portion thereof. In this example, the cavity 416 is a through-hole that separates the substrate 402 into two distinct sections. The first substrate section supports and anchors for the first cantilever 404A. The second substrate section supports and anchors the second cantilever 404B. Furthermore, as shown in FIG. 4, the first cantilever 404A is separated and spaced from the second cantilever 404B via the gap 418 and the gap 420.

As shown in FIG. 4, each cantilever 404A/404B includes an augmentation layer 102, an intermediate layer 408, and a piezoelectric element 406. Each cantilever 404A/404B is anchored or securely attached to at least its corresponding section of the substrate 402. The augmentation layer 102 is disposed between the substrate 402 and the piezoelectric element 406. The intermediate layer 408 is disposed on the augmentation layer 102. In this example, the intermediate layer 408 comprises a dielectric, an insulating layer, or an isolation interlayer. A portion of the augmentation layer 102 is sandwiched between the substrate 402 and the intermediate layer 408. The intermediate layer 408 may cover an entire top surface of the augmentation layer 102.

Also, each piezoelectric element 406 is disposed on the intermediate layer 408. More specifically, each piezoelectric element 406 is in contact with the intermediate layer 408. Each piezoelectric element 406 includes a first electrode 410, a piezoelectric layer 412, and a second electrode 414. The first electrode 410 is in contact with the intermediate layer 408. The piezoelectric layer 412 is between the first electrode 410 and the second electrode 414. The piezoelectric layer 412 has one side in contact with the first electrode 410 and an opposite side in contact with the second electrode 414. In addition, the piezoelectric element 406 of the first cantilever 404A is separated and spaced from the piezoelectric element 406 of the second cantilever 404B via the gap 420 and the gap 418. Also, as shown in FIG. 4, gap 420 is defined to be greater in size than the gap 418. Also, the gap 418 is smaller than the cavity 416. The cavity 416 is greater in size than the gap 420. In this regard, a length of the augmentation layer 102 is greater along the x-axis than a length of the piezoelectric layer 412. In this example, a length of the intermediate layer 408 is the same or substantially the same along the x-axis as a length of the augmentation layer 102. In this example, a length of the first electrode 410 is the same as or substantially the same along the x-axis as a length of the augmentation layer 102. Also, in this example, a length of the first electrode 410 is greater along the x-axis than a length of the second electrode 414. In this example, a length of the first electrode 410 is greater along the x-axis than a length of the piezoelectric layer 412.

With respect to FIG. 4, the MEMS device 400 may be fabricated in a number of different ways. As one example, the method may include depositing an augmentation layer 102 on a substrate 402. The substrate 402 comprises at least one material, as discussed above. The substrate 402 may have a thickness that is no greater than 0.5 mm. When the augmentation layer 102 comprises one or more metamaterial layers 104, the method includes forming one or more types of metastructures on the augmentation layer 102 using additive and/or subtractive structure formation methods. The method includes depositing an intermediate layer 408 on the augmentation layer 102. Next, the method includes depositing a first electrode 410 on the intermediate layer 408. The first electrode 410 may be deposited via physical vapor deposition, chemical vapor deposition, electroplating, sputtering, or any other deposition method. The first electrode 410 comprises platinum, aluminum, gold, molybdenum, tungsten, or another conductor of approximately 100 nm in thickness. The first electrode 410 is formed across the entire length of the intermediate layer 408. The method includes depositing a piezoelectric layer 412 (e.g., PZT, AlN, Al₁₋ₓScₓN, or another piezo material) via sputtering, molecular beam epitaxy, or another deposition method. The piezoelectric layer 412 may have a thickness that is within a range of 0.5 μm to 2 μm. The method includes depositing a second electrode 414 on the piezoelectric layer 412. The second electrode 414 may be deposited via a method similar to or different from the deposition of the first electrode 410. The second electrode 414 comprises platinum, aluminum, gold, molybdenum, tungsten, or another conductor of approximately 100 nm in thickness. Also, the augmentation layer 102, the intermediate layer 408, and the first electrode 410 are formed as shown in FIG. 4 with an gap 418 therebetween. The piezoelectric layer 412 and the second electrode 414 are formed as shown in FIG. 4 with a gap 420 therebetween. A size of the gap 418 is smaller than a size of the gap 420. The method includes removing or etching away a portion of the substrate 402 to create a cavity 416 in the substrate 402 such that (i) a part of the first cantilever 404A is suspended and unsupported by the substrate 402 and (i) a part of the second cantilever 404B is suspended and unsupported by the substrate 402. In addition, the removal of a portion of the substrate 402 exposes a bottom surface of the augmentation layer 102. The bottom surface of the augmentation layer 102 may be directly exposed to an environment of the cavity 416. Furthermore, in addition to the metamaterial layer 104, if desired, the metastructures may be formed on one or more of the other layers of the cantilevers 404A/404B at a suitable time via additive and/or subtractive structure formation methods. As an example, each cantilever 404A/404B may comprise a thickness within a range of 15 mm×2 mm.

FIG. 5 illustrates a cross-sectional view of the piezoelectric device 100, which is configured as MEMS device 500. The MEMS device 500 comprises at least a base 502. The base 502 provides a structure that supports and anchors the cantilever 504. The base 502 comprises a silicon wafer or a glass wafer with a thickness of about 400 μm to 1000 μm. Alternatively, the base 502 comprises a silicon dioxide or silicon nitride layer with a thickness of about a micron. The cantilever 504 includes the augmentation layer 102, a first electrode 506, a piezoelectric layer 508, and a second electrode 510. As shown in FIG. 5, in this example, the augmentation layer 102, the first electrode 506, the piezoelectric layer 508, and the second electrode 510 comprise a same length along the x-axis.

With respect to FIG. 5, the MEMS device 500 may be fabricated in a number of different ways. As one example, the method may include depositing an augmentation layer 102 on substrate. A support structure may include the base 502 and the substrate. The substrate may comprise a silicon wafer or a glass wafer. The substrate has a thickness that is no greater than 0.8 mm. When the augmentation layer 102 comprises one or more metamaterial layers 104, the method includes forming one or more types of metastructures on the augmentation layer 102 using additive and/or subtractive structure formation methods. The method includes depositing a first electrode 506 on the augmentation layer 102. The first electrode 506may be deposited via physical vapor deposition, chemical vapor deposition, electroplating, sputtering, or any other deposition method. The first electrode 506 comprises platinum, aluminum, gold, molybdenum, tungsten, or another conductor of approximately 100 nm in thickness. The first electrode 506 is formed across the entire length of the augmentation layer 102. The method includes depositing a piezoelectric layer 508 (e.g., PZT, AlN, Al₁₋ₓScₓN, or another piezo material) via sputtering, molecular beam epitaxy, or another deposition method. The piezoelectric layer 508 may have a thickness that is within a range of 0.5 μm to 2 μm. The method includes depositing a second electrode 510 on the piezoelectric layer 508. The second electrode 510 may be deposited via a method similar to or different from the deposition of the first electrode 506. The second electrode 510 comprises platinum, aluminum, gold, molybdenum, tungsten, or another conductor of approximately 100 nm in thickness. The method includes removing or etching away the substrate such that the cantilever 504 is formed and suspended. In addition, the removal of the substrate exposes a bottom surface of the augmentation layer 102. Furthermore, in addition to the metamaterial layer 104, if desired, the metastructures may be formed on one or more of the other layers of the cantilever 504 at a suitable time via additive and/or subtractive structure formation methods. As an example, the cantilever 504 may comprise a thickness within a range of 15 mm×2 mm.

FIG. 6 illustrates a cross-sectional view of the piezoelectric device 100, which is configured as MEMS device 600. The MEMS device 600 comprises at least a base 602. The base 602 provides a structure that supports and anchors the cantilever 504. The base 602 comprises a silicon wafer or a glass wafer with a thickness of about 400 μm to 1000 μm. Alternatively, the base 602 comprises a silicon dioxide or silicon nitride layer with a thickness of about a micron. The cantilever 604 includes the augmentation layer 102, a first electrode 606, a piezoelectric layer 608, and a second electrode 610. As shown in FIG. 6, in this example, the piezoelectric layer 608 and the second electrode 610 comprise a same or similar length along the x-axis. The piezoelectric layer 608 and the second electrode 610 define a length of the cantilever 604. In addition, the MEMS device 600 includes (i) a first augmentation section 612A that includes a first section of the augmentation layer 102 and a first section of the first electrode 606 and (ii) a second augmentation section 612B that includes a second section of the augmentation layer 102 and a second section of the first electrode 606. The first augmentation section 612A is spaced from the second augmentation section 612B along the x-axis.

With respect to FIG. 6, the MEMS device 600 may be fabricated in a number of different ways. As one example, the method may include depositing an augmentation layer 102 on a substrate. A support structure may include the base 602 and the substrate. The substrate may comprise a silicon wafer or a glass wafer. The substrate has a thickness that is no greater than 0.8 mm. When the augmentation layer 102 comprises one or more metamaterial layers 104, the method includes forming one or more types of metastructures on the augmentation layer 102 using additive and/or subtractive structure formation methods. The method includes depositing a first electrode 606 on the augmentation layer 102. The first electrode 606 may be deposited via physical vapor deposition, chemical vapor deposition, electroplating, sputtering, or any other deposition method. The first electrode 606 comprises platinum, aluminum, gold, molybdenum, tungsten, or another conductor of approximately 100 nm in thickness. The method includes depositing a piezoelectric layer 608 (e.g., PZT, AlN, Al₁₋ₓScₓN, or another piezo material) via sputtering, molecular beam epitaxy, or another deposition method. The piezoelectric layer 608 may have a thickness that is within a range of 0.5 μm to 2 μm. The method includes depositing a second electrode 610 on the piezoelectric layer 608. The second electrode 610 may be deposited via a method similar to or different from the deposition of the first electrode 606. The second electrode 610 comprises platinum, aluminum, gold, molybdenum, tungsten, or another conductor of approximately 100 nm in thickness. The method includes removing or etching away the substrate such that the cantilever 604 is formed and suspended. In addition, the removal of the substrate exposes a bottom surface of the augmentation layer 102 and parts of the piezoelectric layer 608. In addition, the method includes forming the first electrode 606 and the piezoelectric layer 608 into first and second augmentation sections 612A and 612B, as shown in FIG. 6. Furthermore, in addition to the metamaterial layer 104, if desired, the method may include forming one or more types of metastructures on one or more of the other layers of the cantilever 604 at a suitable time via additive and/or subtractive structure formation methods. As an example, the cantilever 604 may comprise a thickness within a range of 15 mm×2 mm.

FIG. 7 illustrates a cross-sectional view of the piezoelectric device 100, which is configured as MEMS device 700. The MEMS device 700 comprises at least a base 702. The base 702 provides a structure that supports and anchors the cantilever 704. The base 702 comprises a silicon wafer or a glass wafer with a thickness of about 400 μm to 1000 μm. Alternatively, the base 702 comprises a silicon dioxide or silicon nitride layer with a thickness of about a micron. The cantilever 704 includes a substrate 712, the augmentation layer 102, a first electrode 706, a piezoelectric layer 708, and a second electrode 710. As shown in FIG. 7, in this example, the substrate 712, the augmentation layer 102, the first electrode 706, the piezoelectric layer 708, and the second electrode 710 comprise a same length along the x-axis. Each of the substrate 712, the augmentation layer 102, the first electrode 706, the piezoelectric layer 708, and the second electrode 710 extend along a full length of the cantilever 704.

With respect to FIG. 7, the MEMS device 700 may be fabricated in a number of different ways. As one example, the method may include depositing an augmentation layer 102 on a substrate 712. A support structure may include the base 702 and a substrate 712. The substrate 712 may comprise a silicon wafer or a glass wafer. The substrate 712 may have a thickness that is no greater than 0.8 mm. When the augmentation layer 102 comprises one or more metamaterial layers 104, the method includes forming one or more types of metastructures on the augmentation layer 102 using additive and/or subtractive structure formation methods. The method includes depositing a first electrode 706 on the augmentation layer 102. The first electrode 706 is deposited via physical vapor deposition, chemical vapor deposition, electroplating, sputtering, or any other deposition method. The first electrode 706 comprises platinum, aluminum, gold, molybdenum, tungsten, or another conductor of approximately 100 nm in thickness. The method includes depositing a piezoelectric layer 708 (e.g., PZT, AlN, Al₁₋ₓScₓN, or another piezo material) via sputtering, molecular beam epitaxy, or another deposition method. The piezoelectric layer 708 may have a thickness that is within a range of 0.5 μm to 2 μm. The method includes depositing a second electrode 710 on the piezoelectric layer 708. The second electrode 710 may be deposited via a method similar to or different from the deposition of the first electrode 706. The second electrode 710 comprises platinum, aluminum, gold, molybdenum, tungsten, or another conductor of approximately 100 nm in thickness. In addition, the method may include removing or etching away at least a bottom part of the substrate 712 such that the remaining upper part of substrate 712 forms a part of the cantilever 704, which is suspended and unsupported. In this example, the cantilever 704 comprises the substrate 712, the augmentation layer 102, the first electrode 706, the piezoelectric layer 708, and the second electrode 710. Furthermore, in addition to the metamaterial layer 104, if desired, the metastructures may be formed on one or more of the other layers of the cantilever 704 at a suitable time via additive and/or subtractive structure formation methods. As an example, the cantilever 704 may comprise a thickness within a range of 15 mm×2 mm.

FIG. 8 illustrates a cross-sectional view of a piezoelectric device 100, which is configured as MEMS device 800. The MEMS device 800 comprises at least a base 802. The base 802 provides a structure that supports and anchors the cantilever 804. The base 802 comprises silicon wafer or a glass wafer with a thickness of about 400 μm to 1000 μm. Alternatively, the base 802 comprises a silicon dioxide or silicon nitride layer with a thickness of about a micron. The cantilever 804 includes a weight 812, the augmentation layer 102, a first electrode 806, a piezoelectric layer 808, and a second electrode 810. As shown in FIG. 8, in this example, the augmentation layer 102, the first electrode 806, the piezoelectric layer 808, and the second electrode 810 comprise a same length along the x-axis. Each of the augmentation layer 102, the first electrode 806, the piezoelectric layer 808, and the second electrode 810 extend along a full length of the cantilever 804. Meanwhile, as shown in FIG. 8, the weight 812 does not extend a long a full length of the cantilever 804. In contrast, the weight 812 extends along a fraction of the full length of the cantilever 804. Specifically, the cantilever 804 includes a first end portion and a second end portion. The second end portion is opposite to the first end portion. The first end portion is anchored and supported by the base 802. The second end portion includes the weight 812 to contribute to a deformation and/or movement of the cantilever. The weight 812 may be a part of the substrate that remains after a majority of the substrate is removed during the fabrication process. The weight 812 is also suspended as a part of the cantilever 804. The weight 812 may comprise silicon or a portion of a silicon wafer.

With respect to FIG. 8, the MEMS device 800 may be fabricated in a number of different ways. As one example, the method may include depositing an augmentation layer 102 on a substrate. A support structure may include a base 802 and a substrate. The substrate may comprise a silicon wafer or a glass wafer. The substrate may have a thickness that is no greater than 0.8 mm. When the augmentation layer 102 comprises one or more metamaterial layers 104, the method includes forming one or more types of metastructures on the augmentation layer 102 using additive and/or subtractive structure formation methods. The method includes depositing a first electrode 806 on the augmentation layer 102. The first electrode 806 may be deposited via physical vapor deposition, chemical vapor deposition, electroplating, sputtering, or any other deposition method. The first electrode 806 comprises platinum, aluminum, gold, molybdenum, tungsten, or another conductor of approximately 100 nm in thickness. The method includes depositing a piezoelectric layer 808 (e.g., PZT, AlN, Al₁₋ₓScₓN, or another piezo material) via sputtering, molecular beam epitaxy, or another deposition method. The piezoelectric layer 808 may have a thickness that is within a range of 0.5 μm to 2 μm. The method includes depositing a second electrode 810 on the piezoelectric layer 808. The second electrode 810 is deposited via a method similar to or different from the deposition of the first electrode 806. The second electrode 810 comprises platinum, aluminum, gold, molybdenum, tungsten, or another conductor of approximately 100 nm in thickness. The method includes removing or etching a major portion of the substrate such that the cantilever 804 is formed and suspended. The cantilever 804 is formed with a weight 812, which is a remaining part of the substrate that is located at an end portion opposite to the base 802. In addition, the removal of the substrate exposes a bottom surface of that portion of the augmentation layer 102 that does have the weight 812 thereon. Furthermore, in addition to the metamaterial layer 104, if desired, the metastructures may be formed on one or more of the other layers of the cantilever 804 at a suitable time via additive and/or subtractive structure formation methods. In this example, the cantilever 804 comprises a thickness within a range of 15 mm×2 mm.

As described in this disclosure, the embodiments include a number of advantageous features, as well as benefits. For example, each piezoelectric device 100 includes an augmentation layer 102, which enhances and improves a performance of that piezoelectric device 100 as determined by at least a performance metric, such as FoM. In addition, the augmentation layer 102 provides mechanical properties that increases a sensitivity and piezoelectric response of a piezoelectric device 100. The piezoelectric device 100 may include a membrane or a bulk acoustic resonator. The piezoelectric device 100 may include a cantilever. The piezoelectric device 100 may operate in the ultrasound frequency range. The piezoelectric device 100 may be used in various applications (e.g., sonar application, parking sensor of a vehicle, a proximity sensor, etc.)

Also, the augmentation layer 102 is deformable and configured to augment a piezoelectric effect of the piezoelectric layer in response to acoustic pressure such that an augmented voltage differential between the first electrode and the second electrode augments a coupling to a differential in acoustic pressure. The augmentation layer 102 is configured to augment a mechanical deformation in response to a piezoelectric effect of the piezoelectric layer generated by a voltage differential applied between the first electrode and the second electrode. Moreover, the incorporation of the augmentation layer 102 is especially beneficial for various sonic devices, such as PMUTs, microspeakers, microphones, and other audio technology, where large deflections of elements are desired.

Furthermore, the above description is intended to be illustrative, and not restrictive, and provided in the context of a particular application and its requirements. Those skilled in the art can appreciate from the foregoing description that the present invention may be implemented in a variety of forms, and that the various embodiments may be implemented alone or in combination. Therefore, while the embodiments of the present invention have been described in connection with particular examples thereof, the general principles defined herein may be applied to other embodiments and applications without departing from the spirit and scope of the described embodiments, and the true scope of the embodiments and/or methods of the present invention are not limited to the embodiments shown and described, since various modifications will become apparent to the skilled practitioner upon a study of the drawings, specification, and following claims. Additionally, or alternatively, components and functionality may be separated or combined differently than in the manner of the various described embodiments and may be described using different terminology. These and other variations, modifications, additions, and improvements may fall within the scope of the disclosure as defined in the claims that follow.

1. A piezoelectric device comprising:
a base; and
a cantilever having a first end portion anchored by the base and a second end portion unsupported by the base, the cantilever being deformable and including at least
(a) a piezoelectric element that includes a first electrode, a piezoelectric layer, and a second electrode, and
(c) a metamaterial layer that supports the piezoelectric element, the metamaterial layer including metastructures,
wherein the metamaterial layer is deformable and augments a piezoelectric effect of the piezoelectric layer in response to acoustic pressure such that an augmented voltage differential between the first electrode and the second electrode augments a coupling to a differential in the acoustic pressure.

2. The piezoelectric device of claim 1, wherein the metastructures are oriented transverse to or parallel to a contact surface of the metamaterial layer, the contact surface being in contact with another layer.

3. The piezoelectric device of claim 1, wherein:
the cantilever further comprises another metamaterial layer that includes other metastructures; and
the another metamaterial layer is deformable and positioned between the piezoelectric element and the metamaterial layer.

4. The piezoelectric device of claim 1, wherein:
the metastructures are generated at a microscale or a nanoscale; and
the metastructures are a part of an auxetic pattern.

5. The piezoelectric device of claim 1, wherein the metamaterial includes a semiconductor.

6. The piezoelectric device of claim 1, wherein the metamaterial layer has a Poisson's ratio that is a negative value.

7. The piezoelectric device of claim 1, wherein the metamaterial layer has a Poisson's ratio that is greater than 0.4.

8. The piezoelectric device of claim 1, wherein the piezoelectric layer comprises aluminum nitride (AlN), a wurtzite, lead zirconate titanate (PZT), or a perovskite.

9. The piezoelectric device of claim 1, wherein at least a portion of the piezoelectric element includes the metastructures.

10. The piezoelectric device of claim 1, wherein a dimension of the first electrode along a length of the cantilever is different than a corresponding dimension of the second electrode along the length of the cantilever.

11. A microelectromechanical systems (MEMS) device comprising:
a base; and
a cantilever having a first end portion anchored by the base and a second end portion unsupported by the base, the cantilever including at least
(b) a piezoelectric element that includes a first electrode, a piezoelectric layer, and a second electrode, and
(c) an augmentation layer in contact with the first electrode, the augmentation layer having a Poisson's ratio that is less than 0.2 or greater than 0.4.

12. The MEMS device of claim 11, wherein the augmentation layer is a metamaterial layer that includes metastructures.

13. The MEMS device of claim 12, wherein the metastructures are oriented parallel to or transverse to a contact surface of the metamaterial layer, the contact surface being in contact with the first electrode.

14. The MEMS device of claim 12, wherein:
the metastructures are generated at a microscale or a nanoscale; and
the metastructures are a part of an auxetic pattern.

15. The MEMS device of claim 12, wherein the metamaterial layer has a Poisson's ratio that is a negative value.

16. The MEMS device of claim 11, wherein:
the augmentation layer includes a composite of metamaterial layers;
the composite of metamaterial layers include at least (i) a first metamaterial layer comprising first metastructures and (ii) a second metamaterial layer comprising second metastructures; and
the first metastructures are different than the second metastructures.

17. The MEMS device of claim 11, wherein the piezoelectric layer comprises aluminum nitride (AlN), a wurtzite, lead zirconate titanate (PZT), or a perovskite.

18. The MEMS device of claim 11, wherein at least a portion of the piezoelectric element includes metastructures.

19. The MEMS device of claim 11, wherein the augmentation layer comprises a semiconductor.

20. The MEMS device of claim 11, wherein a dimension of the first electrode along a length of the cantilever is different than a corresponding dimension of the second electrode along the length of the cantilever.
